(19) United States
(12) Patent Application Publication
(10) Pub. No.: US 2026/0206353 A1
(43) Pub. Date: Jul. 16, 2026

(54) IMAGE SENSOR

(71) Applicant: Samsung Electronics Co., Ltd., Suwon-si (KR)

(72) Inventors: Ho-Chul JI, Suwon-si (KR); Sung In KIM, Suwon-si (KR); Jongyoon SHIN, Suwon-si (KR); Yeonsoo AHN, Suwon-si (KR); Incheol CHO, Suwon-si (KR)

(73) Assignee: Samsung Electronics Co., Ltd., Suwon-si (KR)

(21) Appl. No.: 19/257,647

(22) Filed: Jul. 2, 2025

(30) Foreign Application Priority Data
Jan. 10, 2025 (KR) 10-2025-0004193

(51) Int. Cl. H10F 39/00

(52) U.S. Cl. CPC H10F 39/811; H10F 39/8063; H10F 39/807

(57) ABSTRACT

Disclosed is an image sensor comprising a substrate including a first surface and a second surface opposite to the first surface, a separation pattern in the substrate and defining a first sensing area and a second sensing area, a short device isolation layer adjacent to the first surface; a local node on the short device isolation layer, and a node doping region in contact with the short device isolation layer. The local node does not vertically overlap the separation pattern. The local node includes polysilicon.

### CROSS-REFERENCE TO RELATED APPLICATION

This application claims priority under 35 U.S.C. § 119 to Korean Patent Application No. 10-2025-0004193 filed on Jan. 10, 2025 in the Korean Intellectual Property Office, the disclosure of which is hereby incorporated by reference in its entirety.

### BACKGROUND

The present inventive concepts relate to image sensors, and more particularly, to image sensors with improved electrical and optical characteristics.

An image sensor may convert photonic images into electrical signals. Recent advances in computer and communication industries have led to strong demands in high performances image sensors in various consumer electronic devices such as digital cameras, camcorders, PCSs (Personal Communication Systems), game devices, security cameras, medical micro cameras, etc.

An image sensor may be classified into a charged coupled device (CCD) and a CMOS image sensor. The CMOS image sensor may have a simple operating method, and a size of its product is possibly minimized because its signal processing circuit is integrated into a single chip. Also, the CMOS image sensor may require relatively small power consumption, which is useful in battery-powered application. In addition, since process technology of manufacturing CMOS image sensors is compatible with CMOS process technology, the CMOS image sensors can decrease in fabrication cost. Accordingly, the use of the CMOS image sensor has been rapidly increasing as a result of advanced in technology and implementation of high resolution.

### SUMMARY

Some embodiments of the present inventive concepts provide image sensors with improved electrical and optical characteristics.

Some embodiments of the present inventive concepts provide image sensors advantageous to fine pixel applications by simplifying contacts between pixels.

The object of the present inventive concepts is not limited to the mentioned above, and other objects which have not been mentioned above will be clearly understood to those skilled in the art from the following description.

According to some embodiments of the present inventive concepts, an image sensor may include substrate including a first surface and a second surface opposite to the first surface; a separation pattern in the substrate and defining a first sensing area and a second sensing area; a short device isolation layer adjacent to the first surface; a local node on the short device isolation layer; and a node doping region in contact with the short device isolation layer. The local node may not vertically overlap the separation pattern. The local node may include polysilicon.

According to some embodiments of the present inventive concepts, an image sensor may include a substrate including a first surface and a second surface opposite to the first surface; a separation pattern in the substrate and defining a first sensing area and a second sensing area; a short device isolation layer adjacent to the first surface; a local node on the short device isolation layer; and a node doping region in contact with the short device isolation layer. The local node may be between portions of the separation pattern adjacent to and spaced apart from each other. The local node may include polysilicon. A top surface of the short device isolation layer may be in contact with a bottom surface of the local node. The node doping region and the local node may be electrically connected to each other.

According to some embodiments of the present inventive concepts, an image sensor may include a substrate having a first surface and a second surface opposite to the first surface; a separation pattern in the substrate and defining sensing areas; photoelectric conversion regions in the substrate; a short device isolation layer adjacent to the first surface of the substrate; transfer gates adjacent to the first surface of the substrate; a local node on the short device isolation layer; a node doping region in contact with the local node; color filters on the second surface of the substrate and corresponding to the sensing areas; and microlenses on the color filters. The local node may be between portions of the separation pattern adjacent to and spaced apart from each other. The local node may include polysilicon. A top surface of the short device isolation layer may be in contact with a bottom surface of the local node. A bottom surface of the node doping region may be at a level between a level of the bottom surface of the local node and a level of a bottom surface of the short device isolation layer.

According to some embodiments of the present inventive concepts, a method of manufacturing an image sensor may include forming photoelectric conversion regions in a substrate, forming a device isolation layer in the substrate, the device isolation layer including a shallow device isolation layer and a short device isolation layer, forming a separation pattern in the shallow device isolation layer, forming node doping regions adjacent to the short device isolation layer, forming a local node on the short device isolation layer, the local node including doped polysilicon, and forming transfer gates in the photoelectric conversion regions.

According to some embodiments of the present inventive concepts, the method of manufacturing the image sensor may include forming a trench by removing a portion of the short device isolation layer below an upper surface of the substrate, the local node being formed in the trench.

Details of other embodiments are included in the description and drawings.

### BRIEF DESCRIPTION OF DRAWINGS

FIG. 1 illustrates a plan view showing an image sensor according to some embodiments of the present inventive concepts.

FIG. 2A illustrates a cross-sectional view taken along line A-A′ of FIG. 1, showing an image sensor according to some embodiments of the present inventive concepts.

FIG. 2B illustrates a cross-sectional view taken along line A-A′ of FIG. 1, showing an image sensor according to some embodiments of the present inventive concepts.

FIG. 2C illustrates a cross-sectional view taken along line A-A′ of FIG. 1, showing an image sensor according to some embodiments of the present inventive concepts.

FIG. 2D illustrates a cross-sectional view taken along line A-A′ of FIG. 1, showing an image sensor according to some embodiments of the present inventive concepts.

FIG. 3 illustrates a plan view showing an image sensor according to some embodiments of the present inventive concepts.

FIG. 4 illustrates a cross-sectional view taken along line A-A′ of FIG. 3, showing an image sensor according to some embodiments of the present inventive concepts.

FIG. 5 illustrates a plan view showing an image sensor according to some embodiments of the present inventive concepts.

FIG. 6A illustrates a cross-sectional view taken along line X-X′ of FIG. 5, showing an image sensor according to some embodiments of the present inventive concepts.

FIG. 6B illustrates a cross-sectional view taken along line Y-Y′ of FIG. 5, showing an image sensor according to some embodiments of the present inventive concepts.

FIG. 7 illustrates a plan view showing an image sensor according to some embodiments of the present inventive concepts.

FIG. 8 illustrates a plan view showing an image sensor according to some embodiments of the present inventive concepts.

FIGS. 9, 10, 11, and 12 illustrate cross-sectional views taken along line A-A′ of FIG. 3, showing an image sensor according to some embodiments of the present inventive concepts.

### DETAILED DESCRIPTION OF EMBODIMENTS

The following will now describe in detail an image sensor according to some embodiments of the present inventive concepts in conjunction with the accompanying drawings.

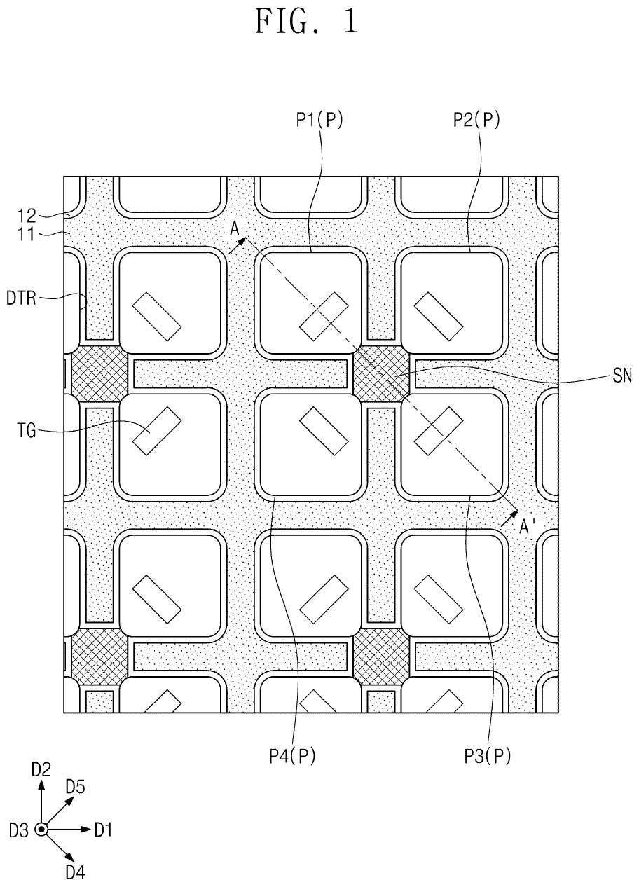

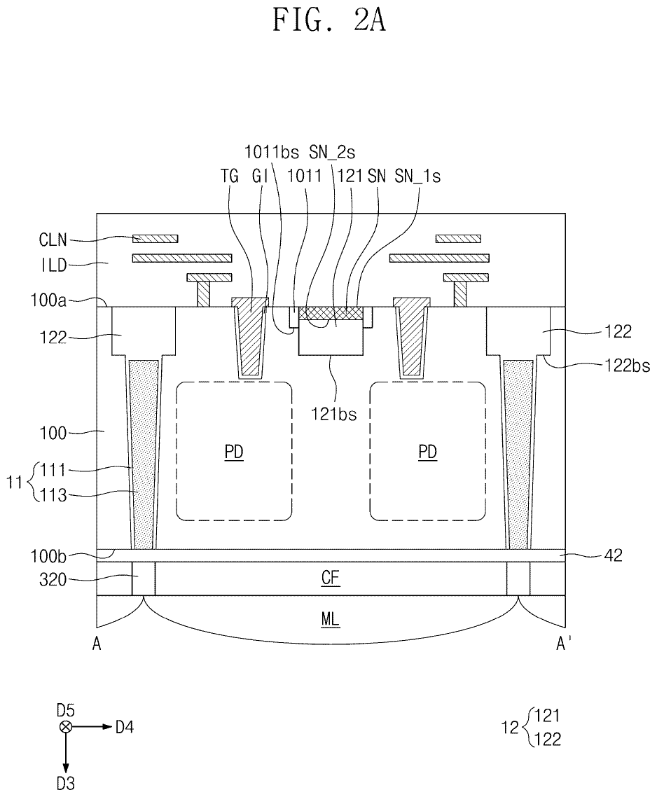

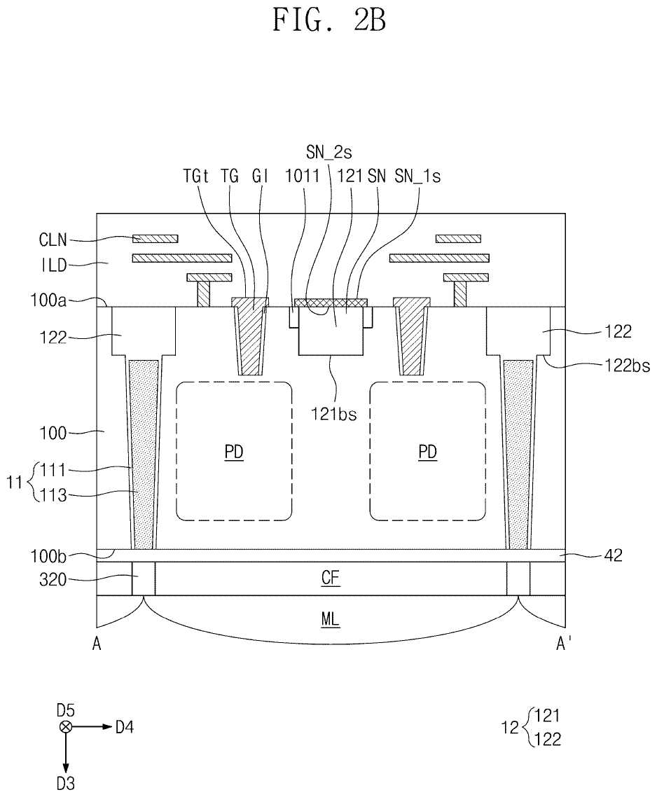

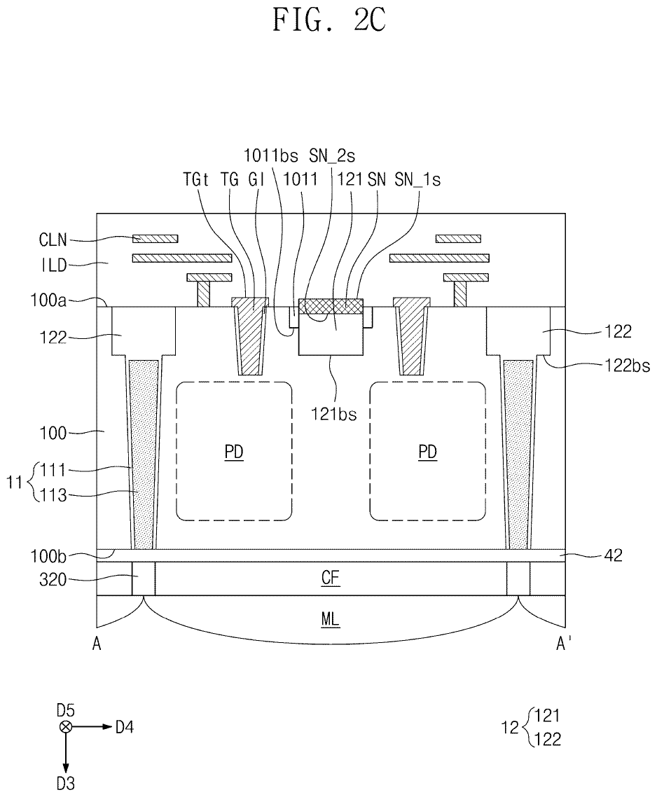

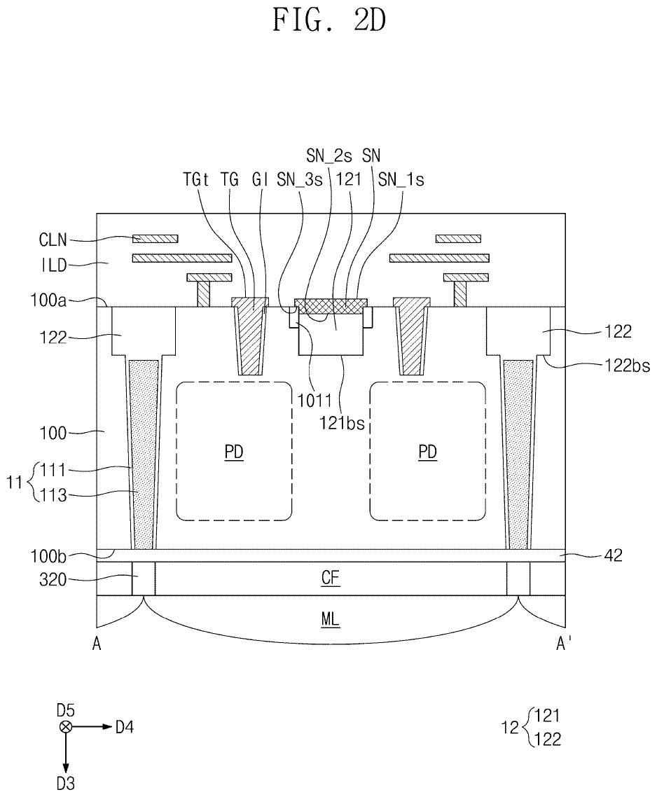

FIG. 1 illustrates a plan view showing an image sensor according to some embodiments of the present inventive concepts. FIG. 2A illustrates a cross-sectional view taken along line A-A′ of FIG. 1, showing an image sensor according to some embodiments of the present inventive concepts.

Referring to FIGS. 1 and 2A, according to some embodiments, an image sensor may include a plurality of sensing areas P that are two-dimensionally arranged, and each sensing area P may convert optical signals to electric signals.

The image sensor according to some embodiments of the present inventive concepts may include a substrate 100 having a first surface 100a and a second surface 100b.

For example, the substrate 100 may be a monocrystalline silicon wafer, a silicon epitaxial layer, or a silicon-on-insulator (SOI) substrate. The substrate 100 may be doped with impurities having a first conductivity type (e.g., p-type). The first surface 100a and the second surface 100b of the substrate 100 may be opposite to each other. The substrate 100 may have a plate shape elongated in a first direction D1 and a second direction D2 crossed with the first direction D1.

The first surface 100a may be spaced apart in a third direction D3 from the second surface 100b. The second surface 100b may be spaced apart in the third direction D3 from the first surface 100a. The third direction D3 may be perpendicular to the first surface 100a and/or the second surface 100b of the substrate 100.

The image sensor according to the present inventive concepts may include a plurality of sensing areas P. For example, the sensing areas P may include first, second, third, and fourth sensing areas P1, P2, P3, and P4 that are sequentially arranged along a clockwise direction. The first and second sensing areas P1 and P2 may be arranged side-by-side along the first direction D1, and the third and fourth sensing areas P3 and P4 may also be arranged side-by-side along the first direction D1. The second and third sensing areas P2 and P3 may be arranged side-by-side along the second direction D2, and the first and fourth sensing areas P1 and P4 may also be arranged side-by-side along the second direction D2. The first and third sensing areas P1 and P3 may be arranged spaced apart from each other in a fourth direction D4. The second and fourth sensing areas P2 and P4 may be arranged spaced apart from each other in a fifth direction D5.

A local node SN may be disposed between the first and third sensing areas P1 and P3 and between the second and fourth sensing areas P2 and P4. A separation pattern 11 may not be provided on an area where the local node SN is disposed.

The separation pattern 11 may define a plurality of sensing areas P. The separation pattern 11 may be placed in a separation trench DTR that extends from the first surface 100a toward the second surface 100b. When viewed in plan, the separation pattern 11 may have a network shape where lines extending in the first and second directions D1 and D2 intersect each other on an area other than the area on which the local node SN is disposed. The separation pattern 11 may penetrate the substrate 100. A plurality of photoelectric conversion regions PD that are spaced apart from each other may be disposed between the extending lines of the separation pattern 11.

The substrate 100 may be provided therein with the separation pattern 11 that separates a plurality of sensing areas P from each other. A device isolation layer 12 may be disposed on the substrate 100 to define an active region. The device isolation layer 12 may include a shallow device isolation layer 122 and a short device isolation layer 121. The device isolation layer 12 may be disposed adjacent to the first surface 100a of the substrate 100. The device isolation layer 12 may have a shape that is inserted from the first surface 100a of the substrate 100. For example, the device isolation layer 12 may include a silicon oxide layer and/or a silicon nitride layer.

When viewed in plan, the device isolation layer 12 may have a network shape where lines extending in the first and second directions D1 and D2 intersect each other.

The short device isolation layer 121 may separate the photoelectric conversion regions PD from each other. The photoelectric conversion region PD may be doped with impurities having, for example, a second conductivity type opposite to the first conductivity type. The second conductivity type may be, for example, an n-type. An n-type impurity region formed in the photoelectric conversion region PD and its adjacent p-type impurity region of the substrate 100 may constitute a PN junction to provide a photodiode.

The substrate 100 may be provided on the first surface 100a with the separation pattern 11 that separates the sensing area P, the shallow device isolation layer 122 connected to the separation pattern 11, and the short device isolation layer 121 provided between the adjacent spaced extending lines of the separation pattern 11 and between the photoelectric conversion regions PD. The shallow device isolation layer 122 and the short device isolation layer 121 may define active regions of the substrate 100.

The separation pattern 11 may include a conductive pattern 113 disposed in the separation trench DTR and a separation dielectric layer 111 that surrounds a lateral surface of the conductive pattern 113. The conductive pattern 113 may include a conductive material, such as metal or impurity-doped polysilicon. The separation dielectric layer 111 may include a silicon oxide layer. The shallow device isolation layer 122 may be provided between the separation pattern 11 and the first surface 100a.

On each sensing area P, a transfer gate TG may be provided on the first surface 100a of the substrate 100. For example, a portion of the transfer gate TG may be buried in the substrate 100. The transfer gate TG may be a vertical type. For example, a first part of the transfer gate TG may extend into the substrate 100 from the first surface 100a of the substrate 100 to be provided in the substrate 100, and a second part of the transfer gate TG may be provided on the first surface 100a of the substrate 100. A portion of the transfer gate TG may extend into the substrate 100. The transfer gate TG may be a gate electrode of a transfer transistor.

Alternatively or additionally, the transfer gate TG may have a planar type that is flat on the first surface 100a of the substrate 100.

A gate dielectric layer GI may be interposed between the transfer gate TG and the substrate 100. A floating region may be provided in the substrate 100 adjacent to one side of the transfer gate TG. The floating region may be doped with a conductivity type opposite to that of the substrate 100. For example, the floating region may be doped with impurities having the second conductivity type.

According to some embodiments of the present inventive concepts, light may be incident on the substrate 100 through the second surface 100b of the substrate 100. Electron-hole pairs may be created from the incident light at the PN junction. These created electrons may migrate toward the photoelectric conversion region PD. When a voltage is applied to the transfer gate TG, the electrons may move to the floating region.

An interlayer dielectric layer ILD may be provided on the first surface 100a of the substrate 100. The interlayer dielectric layer ILD may cover the first surface 100a. The interlayer dielectric layer ILD may be a multiple layer including at least one selected from a silicon oxide layer, a silicon nitride layer, a silicon oxynitride layer, a porous low-k dielectric layer, and a combination thereof. Wiring lines CLN may be provided in the interlayer dielectric layer ILD. The floating region may be connected to the wiring lines CLN. The floating region may be included in a node doping region 1011 which will be discussed below.

A planarization dielectric layer 42 may cover the second surface 100b of the substrate 100. The planarization dielectric layer 42 may be formed of a transparent dielectric material and may include a plurality of layers. The planarization dielectric layer 42 may be formed of a dielectric material whose refractive index is different from that of the substrate 100. The planarization dielectric layer 42 may include one or more of metal oxide and silicon oxide.

A grid structure 320 may be disposed on the planarization dielectric layer 42. Similar to the separation pattern 11, the grid structure 320 may have a mesh or grid shape when viewed in plan. When viewed in plan, the grid structure 320 may overlap the separation pattern 11. For example, the grid structure 320 may include first parts that extend in the first direction D1 and second parts that extend in the second direction D2 while running across the first parts. A width of the grid structure 320 may be the same as, substantially the same as, or less than a minimum width of the separation pattern 11.

The grid structure 320 may include one or more of a light-shield pattern and a low-refractive pattern. The light-shield pattern may include a metallic material, such as titanium, tantalum, and/or tungsten. The low-refractive pattern may be formed of a material whose refractive index is less than that of a conductive pattern. The low-refractive pattern may be formed of an organic material and may have a refractive index of about or exactly 1.1 to about or exactly 1.3. For example, the grid structure 320 may be a polymer layer including silica nano-particles.

A color filter CF may be disposed between patterns of the grid structure 320 and on the planarization dielectric layer 42. The color filter CF may fill spaces defined by the grid structure 320. Based on a unit pixel, the color filter CF may include one of red, green, and blue filters or one of magenta, cyan, and yellow color filters. Alternatively or additionally, one or more of the color filters CF may include an infrared filter.

Microlenses ML may be disposed on the color filters CF. Each of the microlenses ML may have a convex shape with a certain curvature radius. The microlenses ML may be formed of a light-transmitting resin. The microlenses ML may be disposed on corresponding color filters CF.

The local node SN may be provided on the short device isolation layer 121. The node doping region 1011 may be provided to contact the short device isolation layer 121 and the local node SN. The short device isolation layer 121, the local node SN, the node doping region 1011, and a plurality of transfer gates TG may be disposed between the adjacent spaced extending lines of the separation pattern 11. The transfer gate TG may be disposed between the short device isolation layer 121 and the separation pattern 11. The local node SN may not overlap the separation pattern 11. When viewed in plan, the local node SN may be disposed between the extending lines of the separation pattern 11 that are spaced apart in the first direction D1.

The local node SN may include polysilicon. The local node SN may include doped polysilicon. The node doping region 1011 may include polysilicon. The node doping region 1011 may include doped polysilicon. The local node SN and the node doping region 1011 may be doped with impurities having the same conductivity type. The doping with impurities having the same conductivity type may refer to doping with dopants having the same polarity. For example, impurities having the second conductivity type may be doped in the local node SN and/or the node doping region 1011.

A bottom surface SN_2s of the local node SN may be in contact with the short device isolation layer 121. A top surface SN_1s of the local node SN may be in contact with the interlayer dielectric layer ILD. The top surface SN_1s of the local node SN may be coplanar with the first surface 100a of the substrate 100. The top surface SN_1s of the local node SN may be coplanar with a top surface of the node doping region 1011. The top surface SN_1s of the local node SN may be coplanar with a top surface of the shallow device isolation layer 122. The top surface of the shallow device isolation layer 122 may be in contact with the interlayer dielectric layer ILD.

The bottom surface SN_2s of the local node SN may be located at a level higher than that of a bottom surface 1011bs of the node doping region 1011. The level of the bottom surface 1011bs of the node doping region 1011 may be higher than that of a bottom surface 121bs of the short device isolation layer 121. The level of the bottom surface 1011bs of the node doping region 1011 may be higher than that of a bottom surface 122bs of the shallow device isolation layer 122. The bottom surface 121bs of the short device isolation layer 121 may be located at the same or substantially the same level as that of the bottom surface 122bs of the shallow device isolation layer 122. The level of the bottom surface 1011bs of the node doping region 1011 may be present between the level of the bottom surface SN_2s of the local node SN and the level of the bottom surface 121bs of the short device isolation layer 121.

When the terms “about” or “substantially” are used in this specification in connection with a numerical value, it is intended that the associated numerical value includes a manufacturing or operational tolerance (e.g., ±10 %) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10 %) around the stated numerical values or shapes.

In this description, the phrase “a level of one component is higher than a level of another component” may indicate that a distance of one component from the second surface 100b of the substrate 100 is greater than a distance of another component from the second surface 100b of the substrate 100. For example, in this description, the phrase “a level of one component is higher than a level of another component” may denote that a distance of one component from the first surface 100a of the substrate 100 is less than a distance of another component from the first surface 100a of the substrate 100.

In the image sensor according to some embodiments of the present inventive concepts, the short device isolation layer 121 may be provided on an area where the separation pattern 11 is not provided, and the local node SN may be provided on the short device isolation layer 121. The local node SN and the node doping region 1011 may be connected and may be advantageous to a reduction in pixel size.

The microlens ML may be disposed on the second surface 100b of the substrate 100. The photoelectric conversion regions PD, which are adjacent to and spaced apart from each other and between which the separation pattern 11 is not provided, may vertical overlap one microlens ML. The photoelectric conversion regions PD, which are adjacent to and spaced apart from each other, and the short device isolation layer 121 disposed between the photoelectric conversion regions PD may vertical overlap one microlens ML. For example, a plurality of photoelectric conversion regions PD that are spaced apart from each other may be disposed between the adjacent spaced extending lines of the separation pattern 11.

FIG. 2B illustrates a cross-sectional view taken along line A-A′ of FIG. 1, showing an image sensor according to some embodiments of the present inventive concepts. For brevity of description, omission will be made to avoid a repetitive explanation.

Referring to FIG. 2B, the local node SN may be provided on the short device isolation layer 121. A top surface of the short device isolation layer 121 may be coplanar with the first surface 100a of the substrate 100. The top surface of the short device isolation layer 121 may be coplanar with the top surface of the node doping region 1011.

The local node SN may protrude into the interlayer dielectric layer ILD from the first surface 100a of the substrate 100. The local node SN may protrude toward the short device isolation layer 121 from the first surface 100a of the substrate 100. The bottom surface SN_2s of the local node SN may be coplanar with the first surface 100a of the substrate 100. The bottom surface SN_2s of the local node SN may be located at a level higher than that of the bottom surface 121bs of the short device isolation layer 121. The level of the bottom surface SN_2s of the local node SN may be higher than that of the bottom surface 122bs of the shallow device isolation layer 122.

The top surface SN_1s of the local node SN may be in contact (as used herein, “in contact” may additionally or alternatively be understood as “in direct contact”) with the interlayer dielectric layer ILD. The top surface SN_1s of the local node SN may be located at a level lower than that of a top surface TGt of the transfer gate TG and higher than that of the top surface of the node doping region 1011.

The local node SN may cover a portion of the top surface of the node doping region 1011. Thus, the local node SN may be electrically connected to the node doping region 1011. The local node SN may be in contact with the top surface of the short device isolation layer 121 and the top surface of the node doping region 1011. A sidewall of the node doping region 1011 may be in contact with a sidewall of the short device isolation layer 121.

FIG. 2C illustrates a cross-sectional view taken along line A-A′ of FIG. 1, showing an image sensor according to some embodiments of the present inventive concepts. For brevity of description, omission will be made to avoid a repetitive explanation.

Referring to FIG. 2C, the local node SN may be provided on the short device isolation layer 121. The top surface of the short device isolation layer 121 may be located at a level lower than that of the first surface 100a of the substrate 100. The level of the top surface of the short device isolation layer 121 may be lower than that of the top surface of the node doping region 1011. The top surface of the node doping region 1011 may be coplanar with the first surface 100a of the substrate 100.

The local node SN may penetrate the first surface 100a of the substrate 100 and protrude from the interlayer dielectric layer ILD toward the short device isolation layer 121. The local node SN may have a shape that extends into a portion of the interlayer dielectric layer ILD and a portion of the substrate 100.

The top surface SN_1s of the local node SN may be located at a level higher than that of the first surface 100a of the substrate 100. The level of the top surface SN_1s of the local node SN may be higher than that of the top surface of the node doping region 1011.

The bottom surface SN_2s of the local node SN may be located at a level higher than that of the bottom surface 121bs of the short device isolation layer 121. The level of the bottom surface SN_2s of the local node SN may be higher than that of the bottom surface 122bs of the shallow device isolation layer 122. The level of the bottom surface SN_2s of the local node SN may be higher than that of the bottom surface 1011bs of the node doping region 1011. The level of the bottom surface SN_2s of the local node SN may be higher than that of the top surface of the node doping region 1011.

The top surface SN_1s of the local node SN may be in contact with the interlayer dielectric layer ILD. The top surface SN_1s of the local node SN may be located at a level lower than that of the top surface TGt of the transfer gate TG and higher than that of the top surface of the node doping region 1011.

A sidewall of the local node SN may be in contact with the node doping region 1011. The sidewall of the node doping region 1011 may be in contact with the sidewall of the local node SN and the sidewall of the short device isolation layer 121.

FIG. 2D illustrates a cross-sectional view taken along line A-A′ of FIG. 1, showing an image sensor according to some embodiments of the present inventive concepts. For brevity of description, omission will be made to avoid a repetitive explanation.

Referring to FIG. 2D, the local node SN may be provided on the short device isolation layer 121 and the node doping region 1011. The top surface of the short device isolation layer 121 may be located at a level lower than that of the first surface 100a of the substrate 100. The level of the top surface of the short device isolation layer 121 may be lower than that of the top surface of the node doping region 1011. The top surface of the node doping region 1011 may be coplanar with the first surface 100a of the substrate 100.

The local node SN may penetrate the first surface 100a of the substrate 100 and protrude from the interlayer dielectric layer ILD toward the short device isolation layer 121. The local node SN may have a shape that extends into a portion of the interlayer dielectric layer ILD and a portion of the substrate 100.

The top surface SN_1s of the local node SN may be located at a level higher than that of the first surface 100a of the substrate 100. The level of the top surface SN_1s of the local node SN may be higher than that of the top surface of the node doping region 1011.

The bottom surface SN_2s of the local node SN may be located at a level higher than that of the bottom surface 121bs of the short device isolation layer 121. The level of the bottom surface SN_2s of the local node SN may be higher than that of the bottom surface 122bs of the shallow device isolation layer 122. The level of the bottom surface SN_2s of the local node SN may be higher than that of the bottom surface 1011bs of the node doping region 1011. The level of the bottom surface SN_2s of the local node SN may be higher than that of the top surface of the node doping region 1011.

A length of the top surface SN_1s of the local node SN may be greater than a length of the bottom surface SN_2s of the local node SN.

The local node SN may have an intermediate bottom surface SN_3s. The intermediate bottom surface SN_3s of the local node SN may be in contact with the node doping region 1011. The intermediate bottom surface SN_3s of the local node SN may be electrically connected to the node doping region 1011.

The intermediate bottom surface SN_3s of the local node SN may be located at a level higher than that of the bottom surface SN_2s of the local node SN. The level of the intermediate bottom surface SN_3s of the local node SN may be present between the level of the top surface SN_1s of the local node SN and the level of the bottom surface SN_2s of the local node SN. For example, the local node SN may have a step difference in the vicinity of the node doping region 1011.

The top surface SN_1s of the local node SN may be in contact with the interlayer dielectric layer ILD. A sidewall of the local node SN may be in contact with the interlayer dielectric layer ILD. The sidewall of the node doping region 1011 may be in contact with the sidewall of the local node SN and the sidewall of the short device isolation layer 121.

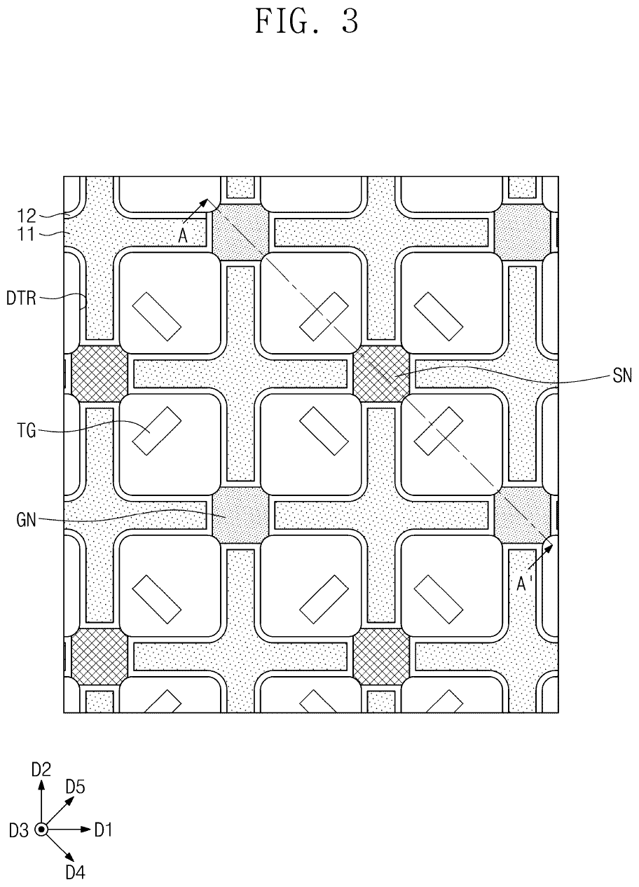

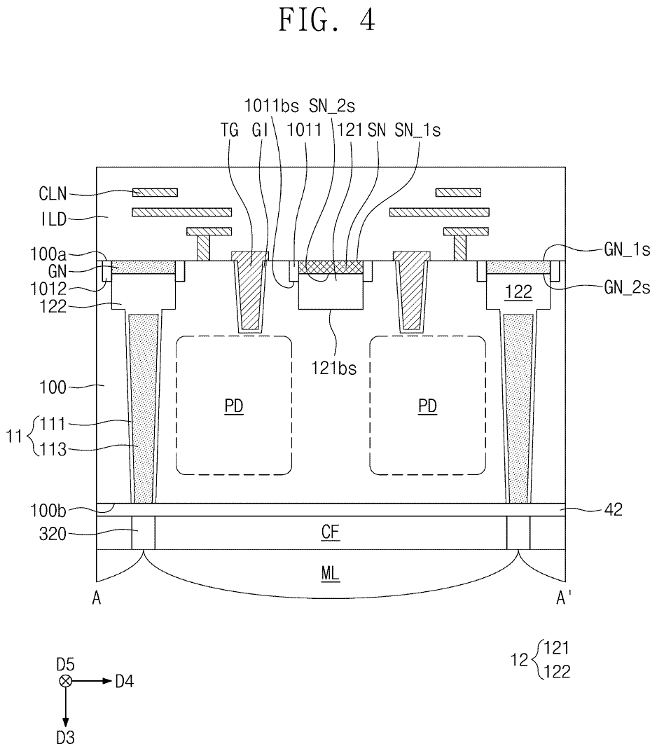

FIG. 3 illustrates a plan view showing an image sensor according to some embodiments of the present inventive concepts. FIG. 4 illustrates a cross-sectional view taken along line A-A′ of FIG. 3, showing an image sensor according to some embodiments of the present inventive concepts. For brevity of description, omission will be made to avoid a repetitive explanation.

Referring to FIGS. 3 and 4, a ground node GN may be provided on the separation pattern 11.

A plurality of ground nodes GN may be disposed spaced apart from each other in the first direction D1 and the second direction D2. A plurality of photoelectric conversion regions P may be provided between the ground nodes GN that are adjacent to and spaced apart from each other. The local node SN may be provided between the ground nodes GN that are adjacent to and spaced apart from each other. FIG. 4 depicts that, similar to the local node SN of FIG. 2A, the top surface SN_1s of the local node SN is coplanar with the first surface 100a of the substrate 100, but the shape of the local node SN is not limited thereto and the local node SN may have any one of the shapes illustrated in FIGS. 2A to 2C. The top surface SN_1s of the local node SN may be located at any levels.

The ground node GN may be disposed between the shallow device isolation layer 122 and the first surface 100a of the substrate 100. The ground node GN may be disposed on the shallow device isolation layer 122. An intervening doping region 1012 may be provided which is in contact with the ground node GN. The intervening doping region 1012 may be in contact with the ground node GN and the shallow device isolation layer 122.

The ground node GN may include polysilicon. The ground node GN may include polysilicon doped with the same dopant as that of the local node SN. The ground node GN may include polysilicon doped with dopants having the same conductivity type as that of dopants doped in the intervening doping region 1012. The doping with dopants having the same conductivity type may refer to doping with dopants having the same polarity.

A top surface GN_1s of the ground node GN may be coplanar with the first surface 100a of the substrate 100. The top surface GN_1s of the ground node GN may be coplanar with the intervening doping region 1012. A bottom surface GN_2s of the ground node GN may be located at a level the same or substantially the same as that of the bottom surface SN_2s of the local node SN. The level of the bottom surface SN_2s of the local node SN may be higher than that of a bottom surface of the intervening doping region 1012.

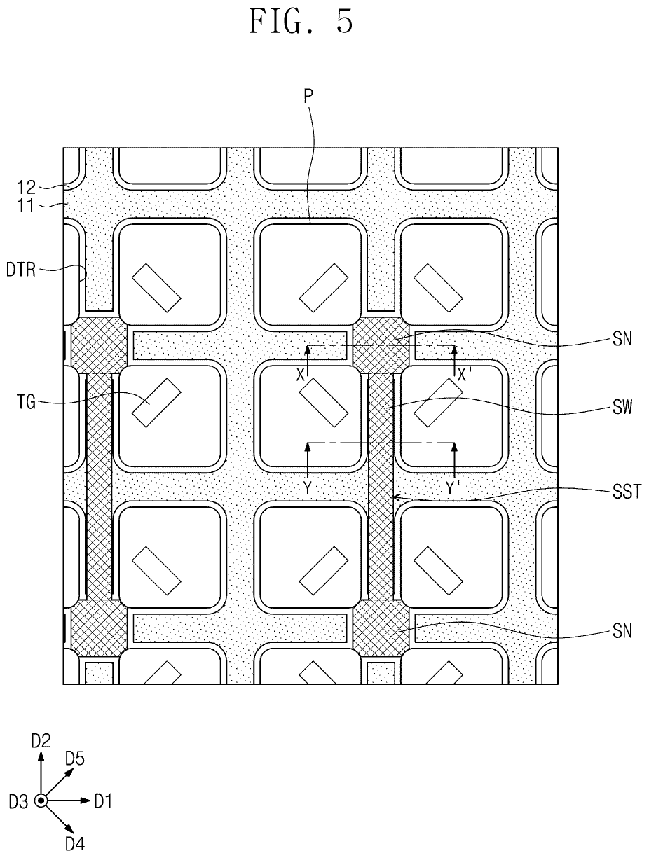

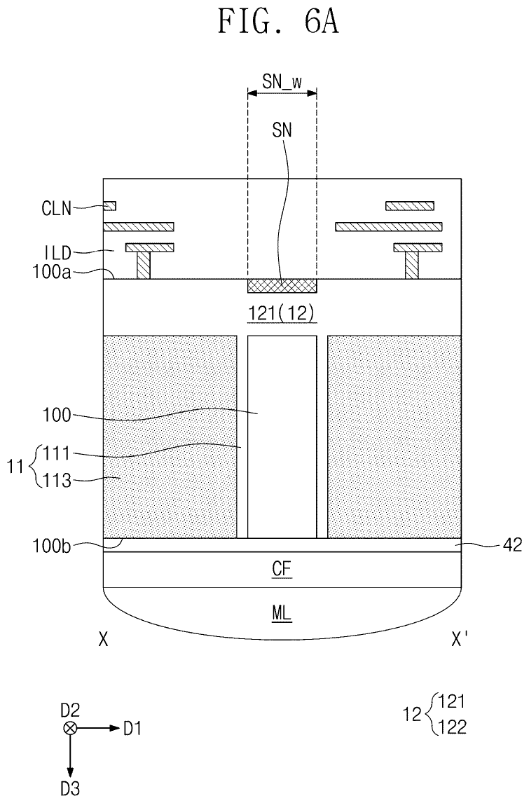

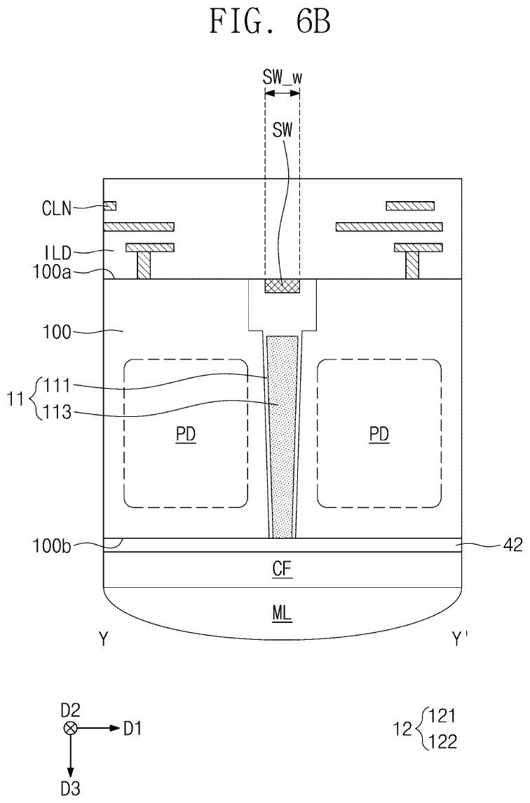

FIG. 5 illustrates a plan view showing an image sensor according to some embodiments of the present inventive concepts. FIG. 6A illustrates a cross-sectional view taken along line X-X′ of FIG. 5, showing an image sensor according to some embodiments of the present inventive concepts. FIG. 6B illustrates a cross-sectional view taken along line Y-Y′ of FIG. 5, showing an image sensor according to some embodiments of the present inventive concepts. For brevity of description, omission will be made to avoid a repetitive explanation.

Referring to FIGS. 5, 6A, and 6B, a local wiring structure SST may be provided which includes local nodes SN and a local line SW. The local wiring structure SST may connect a plurality of sensing areas P to each other.

The local line SW may be disposed between the local nodes SN that are spaced apart from each other. The local line SW and the local nodes SN may include polysilicon doped with dopants having the same conductivity type. The doping with dopants having the same conductivity type may refer to doping with dopants having the same polarity. The local line SW and the local nodes SN may constitute a single unitary piece without any boundary. The local line SW may vertically overlap the separation pattern 11.

The local nodes SN may not vertically overlap the separation pattern 11. The separation pattern 11 may be interposed between the local nodes SN that are spaced apart from each other. The conductive pattern 113 may be disposed between the local nodes SN that are spaced apart from each other, and the separation dielectric layer 111 may be disposed on the lateral surface of the conductive pattern 113. The local nodes SN may be provided on an area where the separation pattern 11 is not provided.

The short device isolation layer 121 may be provided on the conductive pattern 113 and the separation dielectric layer 111. The short device isolation layer 121 may be provided on the area where the separation pattern 11 is not provided, and on the area, the local nodes SN may be provided on the short device isolation layer 121.

The separation pattern 11 may be interposed between a plurality of photoelectric conversion regions PD that are spaced apart from each other. The conductive pattern 113 and the separation dielectric layer 111 that surrounds the conductive pattern 113 may be disposed between a plurality of photoelectric conversion regions PD that are spaced apart from each other. The short device isolation layer 121 may be provided on the separation pattern 11. The local line SW may be disposed in the short device isolation layer 121. The local line SW may have a shape that protrudes toward the short device isolation layer 121 from the first surface 100a of the substrate 100.

A width SW_w of the local line SW may be less than a width of the short device isolation layer 121. The width SW_w of the local line SW may be less than a width SN_w of the local node SN.

The local line SW may connect the local nodes SN to each other. Therefore, the local line SW may electrically connect the local nodes SN without any separate lines.

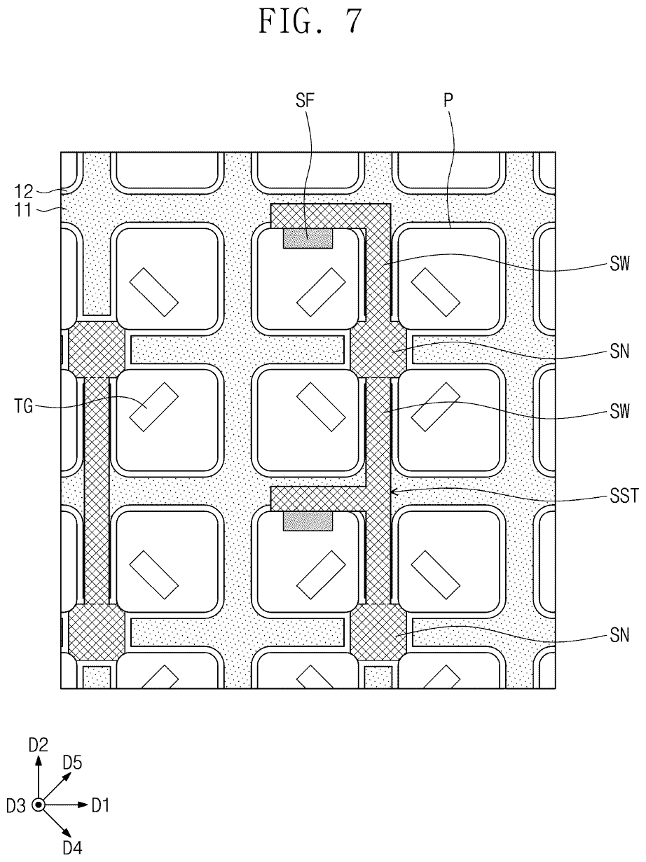

FIG. 7 illustrates a plan view showing an image sensor according to some embodiments of the present inventive concepts. For brevity of description, the following will discuss a difference from the description of FIG. 6.

Referring to FIG. 7, a local wiring structure SST may be provided which includes local nodes SN and a local line SW. The local wiring structure SST may connect a plurality of sensing areas P to each other.

A source follower gate SF may be provided. The local line SW may be disposed between the local nodes SN that are spaced apart from each other. The local line SW may be provided to come into connection with the source follower gate SF. The local line SW may be disposed along the sensing area P. The local line SW may overlap the separation pattern 11.

The local line SW may extend along the sensing area P from the local nodes SN to come into connection with the source follower gate SF. The local line SW may be provided along the separation pattern 11.

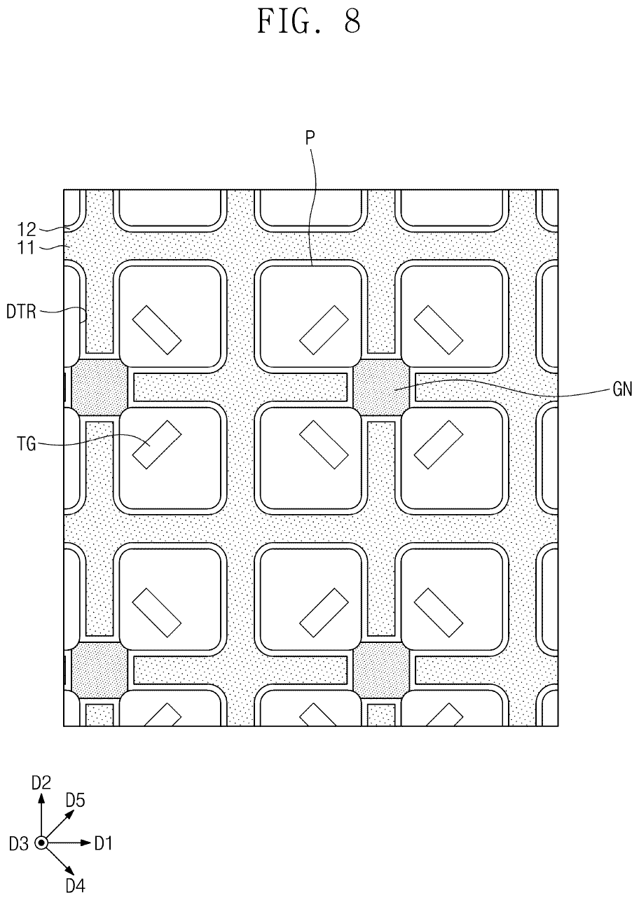

FIG. 8 illustrates a plan view showing an image sensor according to some embodiments of the present inventive concepts. For brevity of description, the following discussion will focus on a difference from the above explanation.

Referring to FIG. 8, a ground node GN may be provided. Four sensing areas P may be provided to enclose the ground node GN. The ground node GN may include, for example, polysilicon, and without the local node SN, only the ground node GN may be provided not to overlap the separation pattern 11. For example, the ground node GN may be disposed on a location of the local node SN shown in FIG. 1.

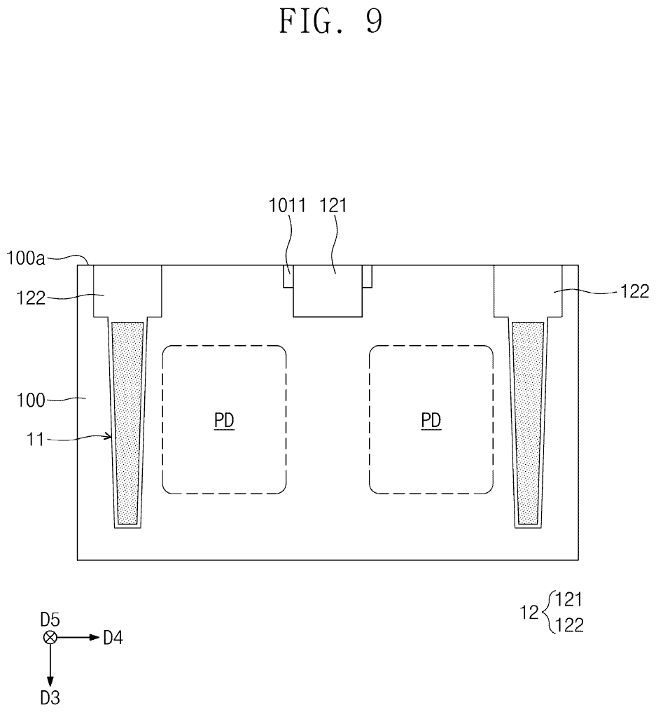

FIGS. 9, 10, 11, and 12 illustrate cross-sectional views taken along line A-A′ of FIG. 3, showing an image sensor according to some embodiments of the present inventive concepts.

Referring to FIG. 9, a photoelectric conversion region PD may be formed in a substrate 100. The substrate 100 may be doped with dopants to form the photoelectric conversion region PD. For example, the photoelectric conversion region PD may be formed by using an ion implantation mask to implant impurities having a second conductivity type.

A device isolation layer 12 and a separation pattern 11 may be formed. A trench may be formed in the substrate 100, and then the trench may be filled with a dielectric material to form the device isolation layer 12.

The separation pattern 11 may be formed by forming a trench in an area of the substrate 100 in which a shallow device isolation layer 122 is formed, and then conformally covering and filling the trench with a dielectric material.

An area where the separation pattern 11 is not formed may be formed between the photoelectric conversion regions PD that are adjacent to each other. A short device isolation layer 121 may be defined to refer to a device isolation layer formed on the area where the separation pattern 11 is not formed. A node doping region 1011 may be formed in the vicinity of the short device isolation layer 121. For example, the node doping region 1011 may be formed by implanting impurities having the second conductivity type.

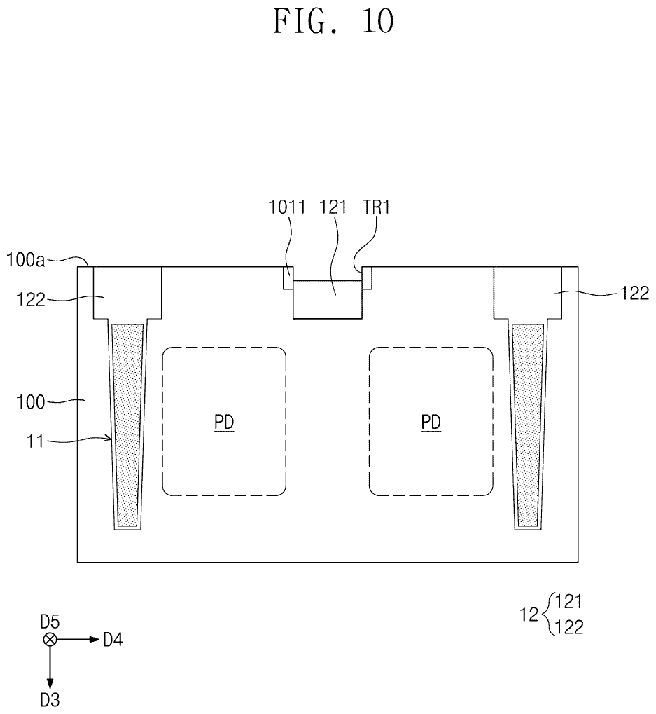

Referring to FIG. 10, a portion of the short device isolation layer 121 may be removed. The partial removal of the short device isolation layer 121 may include using a mask pattern (not shown) to selectively remove only the short device isolation layer 121. The partial removal of the short device isolation layer 121 may form a first trench TR1. The first trench TR1 may expose a top surface of the short device isolation layer 121 and a lateral surface of the node doping region 1011.

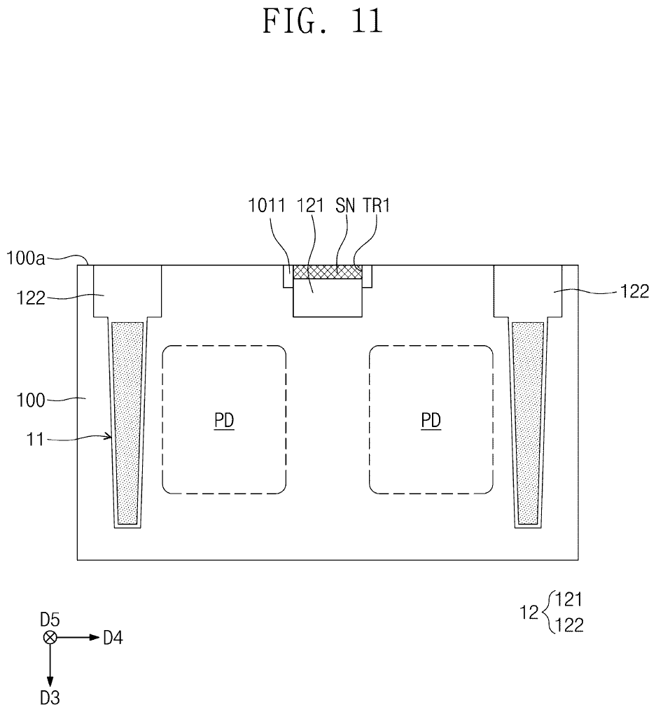

Referring to FIG. 11, the first trench TR1 may be filled with a local node SN. The formation of the local node SN may include filling the first trench TR1 with polysilicon to cover the top surface of the short device isolation layer 121 and the lateral surface of the node doping region 1011. The polysilicon filling the first trench TR1 may include doped polysilicon.

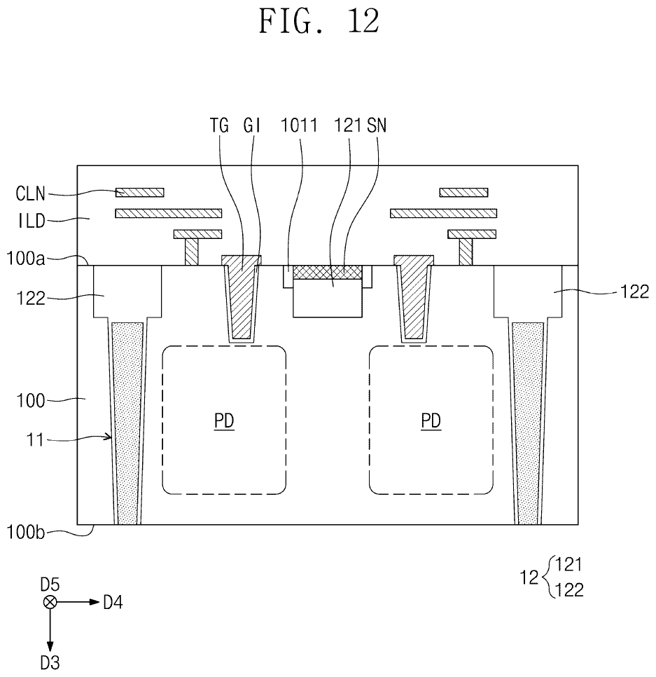

Referring to FIG. 12, a planarization process may be performed to planarize exposed top surfaces of the local node SN and the substrate 100. After that, a transfer gate TG may be formed. The formation of the transfer gate TG may include forming in the substrate 100 a trench in which the transfer gate TG will be formed, covering the trench with a gate dielectric layer GI, forming on the gate dielectric layer GI a transfer gate layer that completely fills the trench, and a portion of the transfer gate layer to form the transfer gate TG.

An interlayer dielectric layer ILD and wiring lines CLN may be provided. The interlayer dielectric layer ILD may be formed on a first surface 100a of the substrate 100. The wiring lines CLN may be formed in the interlayer dielectric layer ILD.

Referring back to FIGS. 1 and 2A, a planarization dielectric layer 42 and a grid structure 320 may be formed on a second surface 100b of the substrate, a color filter CF may be formed between the grid structure 320, and a microlens ML may be formed on the color filter CF. Therefore, an image sensor may be fabricated as shown in FIGS. 1 and 2A.

According to some embodiments of the present inventive concepts, there may be an area where only a short device isolation layer is present without a separation pattern on a boundary between neighboring pixels, and polysilicon may be added to the area to form a floating or ground node in common between neighboring pixels. It may be possible to improve a conversion gain on a unit pixel. In addition, an image sensor may improve in the degree of freedom of wiring.

Moreover, a polysilicon wiring line in contact with the floating node may be formed to achieve an electrical connection with an adjacent gate.

Although the present invention has been described in connection with some embodiments of the present inventive concepts illustrated in the accompanying drawings, it will be understood to those skilled in the art that various changes and modifications may be made without departing from the technical spirit and essential features of the present inventive concepts. It will be apparent to those skilled in the art that various substitution, modifications, and changes may be thereto without departing from the scope and spirit of the present inventive concepts.

What is claimed is

1. An image sensor, comprising:
a substrate comprising a first surface and a second surface opposite to the first surface;
a separation pattern in the substrate, the separation pattern defining a first sensing area and a second sensing area;
a short device isolation layer adjacent to the first surface;
a local node on the short device isolation layer; and
a node doping region in contact with the short device isolation layer,
the local node not vertically overlapping the separation pattern, and
the local node comprising polysilicon.

2. The image sensor of claim 1, wherein the local node extends from the first surface toward the short device isolation layer.

3. The image sensor of claim 1, wherein
a top surface of the short device isolation layer is in contact with the first surface, and
the local node oppositely protrudes from the first surface toward the short device isolation layer.

4. The image sensor of claim 1, wherein the first surface is at a level between a level of a top surface of the local node and a level of a bottom surface of the local node.

5. The image sensor of claim 1, wherein
the local node comprises polysilicon doped with dopants, and
the node doping region comprises polysilicon doped with dopants having a same polarity as a polarity of the dopants doped in the local node.

6. The image sensor of claim 1, further comprising a ground node on the separation pattern,
wherein the ground node comprises polysilicon, and
wherein the ground node and the local node are doped with different dopants.

7. The image sensor of claim 6, wherein a bottom surface of the ground node is at a level same as a level of a bottom surface of the local node.

8. The image sensor of claim 1, further comprising:
a microlens on the second surface of the substrate; and
a photoelectric conversion region vertically overlapping the microlens.

9. The image sensor of claim 1, further comprising a transfer gate adjacent to the first surface of the substrate,
wherein the transfer gate is between the short device isolation layer and the separation pattern.

10. The image sensor of claim 1, wherein
the local node is one of a plurality of local nodes,
when viewed in plan, the plurality of the local nodes are spaced apart from each other in a first direction parallel to a top surface of the substrate and a second direction crossed to the first direction,
a local line between the plurality of local nodes spaced apart from each other, and
the local line and the plurality of local nodes comprise polysilicon doped with dopants having a same polarity.

11. An image sensor, comprising:
a substrate comprising a first surface and a second surface opposite to the first surface;
a separation pattern in the substrate, the separation pattern defining a first sensing area and a second sensing area;
a short device isolation layer adjacent to the first surface;
a local node on the short device isolation layer; and
a node doping region in contact with the short device isolation layer,
the local node between portions of the separation pattern that are adjacent to and spaced apart from each other,
the local node comprising polysilicon,
a top surface of the short device isolation layer in contact with a bottom surface of the local node, and
the node doping region and the local node electrically connected to each other.

12. The image sensor of claim 11, further comprising:
a ground node on the separation pattern; and
an intervening doping region in contact with the ground node,
wherein the ground node and the intervening doping region comprise polysilicon.

13. The image sensor of claim 12, wherein
the local node and the node doping region comprise polysilicon doped with dopants having a same polarity, and
the ground node and the intervening doping region comprise polysilicon doped with dopants having a same polarity.

14. The image sensor of claim 11, wherein
the local node is one of a plurality of local nodes,
when viewed in plan, the plurality of local nodes are spaced apart from each other in a first direction parallel to a top surface of the substrate and a second direction crossed to the first direction, and
a local line between the plurality of local nodes spaced apart from each other.

15. The image sensor of claim 14, further comprising:
a photoelectric conversion region in the substrate and between the separation pattern; and
a source follower gate on the photoelectric conversion region,
wherein the local line and the source follower gate are connected to each other.

16. The image sensor of claim 14, wherein the local line overlaps at least a portion of the separation pattern.

17. The image sensor of claim 11, wherein a top surface of the local node is coplanar with the first surface of the substrate.

18. The image sensor of claim 11, wherein the first surface is at a level between a level of a top surface of the local node and a level of the bottom surface of the local node.

19. The image sensor of claim 11, wherein
the local node comprises an intermediate bottom surface at a level higher than a level of the bottom surface of the local node,
the intermediate bottom surface is in contact with the node doping region.

20. An image sensor, comprising:
a substrate having a first surface and a second surface opposite to the first surface;
a separation pattern in the substrate, the separation pattern defining sensing areas;
photoelectric conversion regions in the substrate;
a short device isolation layer adjacent to the first surface of the substrate;
transfer gates adjacent to the first surface of the substrate;
a local node on the short device isolation layer;
a node doping region in contact with the local node;
color filters on the second surface of the substrate and corresponding to the sensing areas; and
a plurality of microlenses on the color filters,
the local node between portions of the separation pattern that are adjacent to and spaced apart from each other,
the local node comprising polysilicon,
a top surface of the short device isolation layer in contact with a bottom surface of the local node, and
a bottom surface of the node doping region at a level between a level of the bottom surface of the local node and a level of a bottom surface of the short device isolation layer.
